(19) United States
(12) Patent Application Publication
(10) Pub. No.: US 2004/0222812 A1
(43) Pub. Date: Nov. 11, 2004

(54) Integrated circuit having a test circuit

(76) Inventors: Gerd Frankowsky, Hohenkirchen (DE); Robert Kaiser, Kaufering (DE)

Correspondence Address: GERO G. MCCLELLAN, MOSER, PATTERSON & SHERIDAN, L.L.P., Suite 1500, 3040 Post Oak Blvd., Houston, TX, 77056, US

(21) Appl. No.: 10/804,582

(22) Filed: Mar. 19, 2004

(30) Foreign Application Priority Data
Mar. 21, 2003 (DE) 103 13 872.2

(51) Int. Cl. G01R 31/02

(52) U.S. Cl. 324/763

(57) ABSTRACT

The invention relates to an integrated circuit having a test circuit and a test terminal, it being possible for the test circuit to be activated by means of a test signal which can be applied to the test terminal in order to start a test function, a switching device being provided in order, after the activation of the test circuit, to connect the test terminal to an internal voltage line, in order to supply a current requirement needed on account of the test function that is performed.

### CROSS-REFERENCE TO RELATED APPLICATIONS

This application claims foreign priority benefits under 35 U.S.C. §119 to co-pending German patent application number 103 13 872.2, filed Mar. 21, 2003. This related patent application is herein incorporated by reference in its entirety.

### BACKGROUND OF THE INVENTION

1. Field of the Invention

The invention relates to an integrated circuit having a test circuit, which can be activated via a test terminal.

2. Description of the Related Art

Integrated circuits are usually tested during and after their fabrication, before they are delivered to the customer. The integrated circuits are tested by being connected to a tester device via test terminals provided therefor and by the tester device calling up functions within the integrated circuit in accordance with a predetermined test sequence. After the read-out of signals at output terminals, the functions are checked with regard to their correct functioning.

During testing, the integrated circuits are connected to the tester device via the test terminals connected to test lines. During testing, the test lines represent an eye of a needle since, via said test lines, command and data signals are fed to the integrated circuit and output signals are read out from the integrated circuit to the tester device. In order to accelerate the test sequences, test circuits are often integrated within the integrated circuits. The test circuits can be activated by a test signal, so that the internal test circuit performs a test function, which is essentially performed within the integrated circuit without external control. Only the result of the test function or whether or not the result has an error is communicated to the tester device. This makes it possible to drastically reduce the volume of data to be transferred between the integrated circuit and the tester device.

The functions of integrated circuits often require further internally generated voltages. These internally generated voltages are generated for example by voltage dividers, charge pumps or the like. During the testing of the integrated circuit by the internal test circuit, a plurality of functions that are usually independent of one another are often performed simultaneously within the integrated circuit. These mutually independent functions may require internally generated voltages. By virtue of the fact that the functions for testing are essentially performed as far as possible in parallel, the current requirement from the internal voltage sources is higher than in normal operation. The extent of parallelism during the testing of the integrated circuit by the test circuit is therefore limited by the power consumption of the individual circuit parts with regard to the internal voltage sources since only a specific quantity of current can be supplied via the internal voltage sources made available for normal operation of the integrated circuit. Consequently, the test function performed by the test circuit must be configured such that the testing of the circuit parts of the integrated circuit does not cause the current from an internal voltage source to exceed a specific maximum value. As a result, the test operation is prolonged since fewer circuit parts can be tested simultaneously.

After the testing of the integrated circuit, the voltage values of internal voltage sources are set to the desired value. During testing, the internal voltages are present only in uncalibrated fashion, i.e., the voltages have not yet been set to an exact voltage value. The voltages of the internal voltage source are usually set after the conclusion of the test method by the writing of setting values to a permanent memory, e.g., to electrical fuses, or by the severing of interconnects, the so-called laser fuses, by a subsequent laser trimming process. As long as the internally generated voltages do not have exactly the prescribed value, the testing of the functions remains inaccurate and, under certain circumstances, leads to erroneous test results.

### SUMMARY OF THE INVENTION

It is an object of the present invention to provide an improved integrated circuit which enables the testing of an integrated circuit to be carried out more accurately and more rapidly.

A first aspect of the present invention provides an integrated circuit having a test circuit and a test terminal. The test circuit can be activated by means of a test signal which can be applied to the test terminal in order to start an internal test function. Furthermore, a switching device is provided in order, after the activation of the test circuit via the test terminal, to connect the test terminal to an internal voltage line in order to supply a current requirement needed on account of the test functions that are performed.

Integrated circuits generally have a series of internal voltage generators which generate internal voltages for the normal operation of the integrated circuit. The current consumption from the internal voltage generators of the integrated circuit is increased during testing, however, in particular during the simultaneous testing of a plurality of circuit parts within the integrated circuit. The simultaneous testing of a plurality of circuit parts can cause the current-supplying capability of the internal voltage generators of the integrated circuit to be exceeded, so that the parallelism of the testing of the circuit parts within the integrated circuit is thereby limited. Since generally there are no additional external terminals available for the application of further voltages, it is therefore necessary according to the prior art to cause the test functions of the integrated circuit that are performed to proceed successively such that a maximum current from the internal voltage generators is not exceeded. This considerably delays the test sequence.

The invention now provides for an integrated circuit to be provided in which an internal voltage source can be supported or replaced by an external applied voltage. For this purpose, a switching device is provided, which is connected to a test terminal and makes it possible to connect the test terminal to a test circuit for the activation of the test function or to an internal supply line. The switching device thus serves for activating the test circuit with the aid of a test signal and subsequently for connecting the test terminal to an internal voltage line through switching of the switching device.

In this way, in a test system with a test device connected to the integrated circuit to be tested via a test line, it is possible to activate a test circuit in the integrated circuit by applying a test signal. Once the test function has been started by the application of the test signal, the test device applies a current or voltage source via the test line to the integrated circuit, in which the test terminal is connected to an internal voltage line after the test function has been started. By means of the current/voltage source of the test device, it is possible to cover an additional current requirement on the internal voltage line within the integrated circuit while carrying out the test operation.

A further advantage of the integrated circuit according to the invention is that an internally generated voltage can be prescribed externally during testing. The external voltage can be set precisely to a specific voltage value. This is advantageous in particular when the internal voltage source has not yet been set to an optimum voltage value after the conclusion of the test method in an adjustment operation. In this case, during the test operation, the internal voltage source is at a voltage value that has not yet been adjusted, so that the result of the test operation is inaccurate or corrupted.

It is preferably provided that the switching device is driven in such a way as to isolate the test terminal from the test circuit after the activation of the test circuit. This ensures that voltage fluctuations at the test terminal have no influence on the performance of the test function within the test circuit.

A preferred embodiment provides for the integrated circuit to have a memory element in which an activation information item can be stored depending on the application of the test signal. In other words, as soon as the test signal has been received via the test terminal, the activation information is stored in the memory element. The memory element is coupled to the switching device in such a way as to switch the switching device upon storage of the activation information, so that the internal supply line is connected to the test terminal after the application of the test signal.

A further aspect of the present invention provides a method for activating a test function in an integrated circuit. For this purpose, a test signal is applied to a test terminal in order to start a test function in the integrated circuit by means of the test signal. After application of the test signal to the test terminal, an external current or an external voltage is applied in order to provide a current supply for the sequence of the test functions activated by the test signal.

### BRIEF DESCRIPTION OF THE DRAWINGS

A preferred embodiment of the invention is explained in more detail below with reference to the accompanying drawings, in which:

FIG. 1 shows an integrated circuit with a test terminal in accordance with a preferred embodiment of the invention; and

FIG. 2 shows a possible embodiment of a switching device which can be used in the integrated circuit according to the invention.

### DETAILED DESCRIPTION OF THE PREFERRED EMBODIMENT

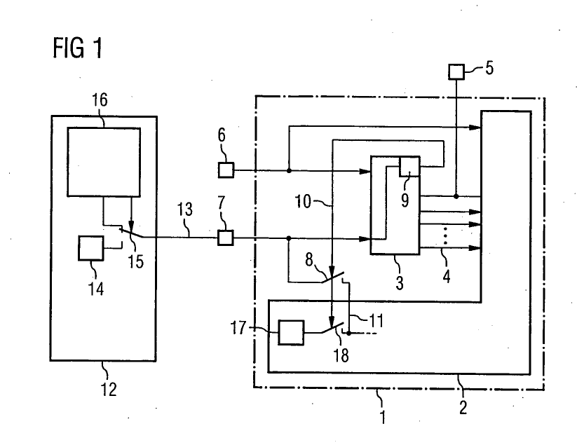

FIG. 1 illustrates a preferred embodiment of the integrated circuit according to the invention. The integrated circuit 1 comprises a useful circuit 2, in which the application-related useful functions of the integrated circuit are realized. The integrated circuit 1 furthermore has a test circuit 3 connected to the useful circuit 2 via control lines 4 in order to test the useful circuit 2 in accordance with a predetermined test sequence implemented in the test circuit 3.

Via a supply voltage terminal 5, both test circuit 3 and useful circuit 2 are connected to a supply voltage.

The useful circuit furthermore has an internal voltage source 17 in order to provide internally generated voltages of the useful circuit 2. The internally generated voltages may be greater or less than the supply voltage that is made available. The internal voltage source 17 may have a charge pump for generating a higher internal voltage or a voltage divider in order to generate an internal voltage from the supply voltage.

Via a data terminal 6, which is connected both to the test circuit 3 and to the useful circuit 2, data can be transferred to the test circuit 3 and, respectively, to the useful circuit 2. The data may be used, on the one hand, to control the test sequence within the test circuit 3 and, on the other hand, during normal operation, to make data available to the useful circuit 2 or to afford the useful circuit 2 the possibility of outputting data.

The test circuit 3 can furthermore be driven via a test terminal 7. The test terminal 7 serves to receive a test signal, whereby the test circuit 3 is activated. Upon activation of the test circuit, a test sequence implemented in the test circuit 3 is started, which test sequence tests the functions of the useful circuit 2 in accordance with a predetermined test method. In circuits in accordance with the prior art, the test terminal 7 is not used any further once the test sequence has been started. It often happens that the test terminal is not available to a later user of the integrated circuit since the test terminal is not connected to a connecting pin of the housing in the event of subsequent housing encapsulation.

Depending on the test function performed in the test circuit 3, particularly in the case of parallel test functions, it may be that there is an increased current requirement from the internal voltage source 12. Under certain circumstances, this current requirement cannot be covered by the internal voltage source 17 present. In this case, in conventional integrated circuits, an additional current supply would have to be fed to the integrated circuit 1 via a further external terminal or the test functions would have to be performed to a lesser extent in parallel or successively in order to reduce the current loading.

Since the number of available external terminals of an integrated circuit is generally limited, it is often not possible to provide any additional voltage terminals that are to be utilized exclusively for carrying out test methods. On the other hand, performing test functions successively would considerably prolong the test time.

Furthermore, it may be necessary to provide an additional voltage potential for carrying out the test functions, said additional voltage potential not being provided for the normal operation of the integrated circuit. Since the available terminals are usually allocated, there is no possibility for introducing said additional voltage potential into the integrated circuit.

According to the invention, therefore, the test terminal 7 is connected to a switching device 8, so that the test terminal 7 can be connected in switchable fashion to an internal voltage line for supplying the circuits with an internal voltage in the useful circuit 2.

The test circuit 3 furthermore has a memory element 9, e.g. in the form of a latch, which can store an activation information item as soon as the test circuit 3 has been activated by the test signal via the test terminal 7. The output of the memory element 9 is connected to the first switching device 8 via a control line 10, so that the first switching device 8 is controlled by the activation information. The control line 10 is furthermore connected to a second switching device 18, so that the second switching device is controlled by the activation information. If an activation information item which specifies that the test function of the test circuit 3 has been activated is stored in the memory element 9, then the first switching device 8 switches, so that the test terminal 7 is connected to the internal voltage network 11.

In the event of an activation of the test function of the test circuit 3, the second switching device 18 may equally be switched such that the internal voltage source 17 is isolated from the internal voltage line, so that the externally applied voltage at the test terminal 7 does not lead to a current flow through the internal voltage source 17.

The integrated circuit is connected to a test device 12 for the activation of the test function and evaluation of the test result. The tester device 12 can apply the test signal to the test terminal 7 via a test line 13. The test device 12 is configured in such a way that, in order to start the test function, the test signal can be applied to the integrated circuit 1 via the test channel of the test line 13 and, after the activation of the test function, a current or supply voltage source 14 is connected to the same test channel. The current or supply voltage source 14 is adjustable in the test device 12.

The connection of the current/voltage source 14 is preferably effected via a switch 15, which is controlled by the test device 12 or by a control module 16 in the test device 12.

In accordance with the method according to the invention, the control module 16 firstly generates the test signal, which is applied to the test terminal 7 via the switch 15 via the test line 13. This has the effect that the test function is started in the test circuit 3 of the integrated circuit 1 and the activation information is stored in the memory element 9. As a result, the first switching device 8 is switched, so that the test terminal 7 is now connected to the internal voltage line 11 and the internal voltage source 17 is isolated from the internal voltage line 11.

Essentially at the same time as or shortly after the transmission of the test signal, the control module 16 drives the switch 15, so that the latter is switched and the current/voltage source 14 is now connected to the test line 13, as a result of which a voltage or a current is applied to the test terminal 7. Consequently, an additional current or a further voltage may be made available to the internal voltage line 11, so that, in the useful circuit 2, it is possible to carry out test functions with higher parallelism, which require an increased current supply. In this way, it is possible that the test circuit 3 can test a plurality of functions simultaneously in parallel in the useful circuit 2 without the current-supplying capability of the internal voltage source 17 being exceeded. Moreover, the possibility of applying an additional voltage represents a possibility of providing a further voltage potential for carrying out the test function to the internal circuits without providing a further test terminal therefor in this case.

A further advantage of the invention is that the externally applied voltage can be set very accurately by the test device and, consequently, the test functions can already be carried out with an adjusted voltage value. The internal voltage sources have not yet been adjusted particularly in the event of testing with the semiconductor chips in an unsawn state. An adjustment of the internal voltage sources is preferably carried out by means of permanent memories or by means of so-called fuses which are programmed only after the test operation has proceeded, so that the desired internal voltage is made available by the internal voltage source.

By virtue of the fact that the internal voltage source is replaced by an external voltage source during the test operation, it is possible to set the internal voltage on the voltage line to the desired value very exactly and thus to carry out the test operation at a defined internal voltage. This enables the functions of the useful circuit to be checked reliably and prevents the testing of the integrated circuit from leading to erroneous test results.

It goes without saying that the switch 15 and/or the switching device 8 may also be provided as changeover switches which isolate the control module 16 and/or the test circuit 3 from the test line simultaneously or after the switching for supplying the test function. This has the advantage that the test circuit 3 cannot be influenced by voltage fluctuations at the test terminal.

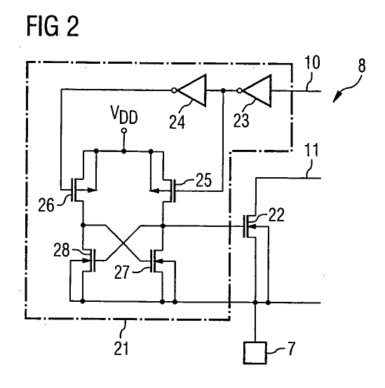

FIG. 2 shows by way of example a circuit of a switching device 8 which can be used to switch supply voltages below the ground potential used in the useful circuit 2. This is a problem particularly because the switching devices are generally realized with the aid of field-effect transistors. If a supply voltage potential lying below the ground potential or the lowest potential used in the circuit is present at a terminal of a field-effect transistor, then the relevant field-effect transistor cannot be completely switched off by means of the voltages available in the integrated circuit, since the lowest available potential is generally the ground potential and a positive gate-source voltage thus exists.

FIG. 2 illustrates a possible first switching device 8, which can be used to carry out a switching of a voltage which has been applied to a test terminal 7, even when the voltage potential lies below the internal ground potential. For this purpose, the first switching device 8 has a voltage level converter circuit 21, which is connected to the control line 10 and provides a drive signal for a gate terminal of a switching transistor 22.

The voltage level converter circuit 21 is furthermore connected to a first high supply voltage potential VDD, which is provided as standard in the integrated circuit, and to the test terminal 7. The switching transistor 22 is likewise connected to the test terminal 7 by a first terminal and to the internal voltage line 11 by a second terminal, the voltage potential applied to the test terminal 7 being applied to said voltage line.

If the high supply voltage potential is present at the gate terminal of the switching transistor 22, then the switching transistor 22 is activated and the voltage potential via the test terminal 7 is present on the internal voltage line 11. In order that the switching transistor 22 turns off completely, a potential which is either equal to or less than the voltage potential present at the test terminal 7 must be present at the gate terminal.

For this purpose, the voltage level converter circuit 21 has a first inverter 23, the input of which is connected to the output of the memory element 9 via the control line 10. The output of the inverter 23 is connected to an input of a second inverter 24 and a gate terminal of a first p-channel transistor 25. An output of the second inverter 24 is connected to a gate terminal of a second p-channel transistor 26. First terminals of the first p-channel transistor 25 and of the second p-channel transistor 26 are connected to the high supply voltage potential VDD.

A second terminal of the first p-channel transistor 25 is connected to the gate terminal of the switching transistor 22, a first terminal of a first n-channel transistor 27 and a gate terminal of a second n-channel transistor 28. A second terminal of the second p-channel transistor 26 is connected to the gate terminal of the first n-channel transistor 27 and a first terminal of the second n-channel transistor 28. Second terminals of the first n-channel transistor 27 and of the second n-channel transistor 28 are connected to the test terminal 7. The substrate terminals of the first p-channel transistor 25 and of the second p-channel transistor 26 are connected to the high supply voltage potential VDD and the substrate terminals of the first n-channel transistor 27 and of the second n-channel transistor 28 are connected to the control terminal 7. The substrate terminal of the switching transistor 22 is likewise connected to the test terminal 7.

In this way, a voltage level converter 21 is provided, which, depending on the activation information, opens or completely turns off the switching transistor 23, even if an external voltage is connected to the test terminal 7 which lies below the ground potential made available in the integrated circuit 1.

The idea of the invention consists in utilizing a test line, via which a test command for starting a test operation in an integrated circuit 1 is made available, for providing a voltage or current supply after the test operation has been started. The voltage or current supply may serve, on the one hand, for providing an increased current supply on an internal voltage line of the integrated circuit 1, in order that it is possible to carry out test methods for a plurality of circuit parts of the useful circuit 2 in parallel, and, on the other hand, for providing the internal voltage during testing more exactly than can be generated by the internal voltage source 17 during the test sequence.

What is claimed is:

1. An integrated circuit, comprising:
a useful circuit comprising an internal voltage line;
a test circuit for testing the useful circuit;
a test terminal coupled to the test circuit in order to provide an activation signal activating the test circuit to perform a test function; and
a switching device to selectively couple the test terminal to the internal voltage line during testing of the test circuit.

2. The integrated circuit of claim 1, wherein the test terminal is coupled to the internal voltage line to provide an electrical signal to the internal voltage line from an external source.

3. The integrated circuit of claim 1, wherein the switching device is further configured to isolate the test terminal from the test circuit after the activation of the test circuit.

4. The integrated circuit of claim 1, wherein the useful circuit further comprises an internal voltage supply.

5. The integrated circuit of claim 4, further comprising another switching device responsive to the switching signal to selectively couple the internal voltage supply to the internal voltage line.

6. The integrated circuit of claim 5, wherein the switching devices are operated reciprocally so that when the test device is coupled to the internal voltage line the internal voltage supply is disconnected from the internal voltage supply.

7. An integrated circuit, comprising:
a useful circuit comprising an internal voltage line;
a test circuit for testing the useful circuit;
a test terminal coupled to the test circuit in order to provide an activation signal activating the test circuit to perform a test function; and
a switching device coupled to an output of the test circuit and configured to selectively couple the test terminal to the internal voltage line in response to a switching signal from the output.

8. The integrated circuit of claim 7, wherein the test circuit is configured to output the switching signal in response to receiving the activation signal.

9. The integrated circuit of claim 7, wherein the test terminal is coupled to the internal voltage line to provide an electrical signal to the internal voltage line from an external source.

10. The integrated circuit of claim 7, wherein the switching device is further configured to isolate the test terminal from the test circuit after the activation of the test circuit.

11. The integrated circuit of claim 7, wherein the test circuit comprises a memory element to store an activation information item dependent on the application of the activation signal, and wherein the switching signal is issued by the test circuit in response to storing the activation information item.

12. The integrated circuit of claim 7, wherein the test circuit is configured to deactivate after the integrated circuit has been connected to a voltage supply.

13. The integrated circuit of claim 7, wherein the useful circuit further comprises an internal voltage supply.

14. The integrated circuit of claim 13, further comprising another switching device responsive to the switching signal to selectively couple the internal voltage supply to the internal voltage line.

15. The integrated circuit of claim 14, wherein the switching devices are operated reciprocally so that when the test device is coupled to the internal voltage line the internal voltage supply is disconnected from the internal voltage supply.

16. A test system for testing an integrated circuit, comprising:
a useful circuit comprising an internal voltage line;
a test circuit for testing the useful circuit;
a test terminal coupled to the test circuit in order to provide an activation signal activating the test circuit to perform a test function;
a switching device coupled to an output of the test circuit and configured to selectively couple the test terminal to the internal voltage line in response to a switching signal from the output; and
an external test device connected to the integrated circuit via the test terminal and comprising (i) a test module for issuing the activation signal; and (ii) a power supply for providing an electrical signal to the internal voltage line after the activation of the test circuit.

17. The test system of claim 16, wherein the external test device further comprises an external test device switch for selectively coupling the test module and power supply to the test terminal.

18. The test system of claim 16, wherein the test circuit is configured to output the switching signal in response to receiving the activation signal.

19. The test system of claim 16, wherein the switching device is further configured to isolate the test terminal from the test circuit after the activation of the test circuit.

20. The test system of claim 16, wherein the useful circuit further comprises an internal voltage supply.

21. The integrated circuit of claim 20, further comprising another switching device responsive to the switching signal to selectively couple the internal voltage supply to the internal voltage line.

22. The integrated circuit of claim 21, wherein the switching devices are operated reciprocally so that when the test device is coupled to the internal voltage line the internal voltage supply is disconnected from the internal voltage supply.

23. A method for testing an integrated circuit comprising a test circuit and a useful circuit to be tested by the test circuit, the method comprising:
applying an activation signal to a test terminal of the integrated circuit while the test terminal is coupled to the test circuit and disconnected from an internal voltage line of the useful circuit; and
activating a first switch to couple the test terminal to the internal voltage line after application of the activation signal, whereby the internal voltage line is provided with external power for the testing.

24. The method of claim 23, wherein the activation signal activates the test circuit to perform a test.

25. The method of claim 23, wherein the first switch is activated in response to an output signal issued by the test circuit in response to the activation signal.

26. The method of claim 25, further comprising activating a second switch in response to the output signal to disconnect an internal power supply from the internal voltage line.

27. The method of claim 23, further comprising disconnecting the test terminal from the test circuit upon activating the first switch.

28. The method of claim 27, activating a second switch in response to the output signal to disconnect an internal power supply from the internal voltage line.
